(19) United States
(12) Patent Application Publication
(10) Pub. No.: US 2026/0112580 A1
(43) Pub. Date: Apr. 23, 2026

(54) PLASMA PROCESSING METHOD AND PLASMA PROCESSING APPARATUS

(71) Applicant: Tokyo Electron Limited, Tokyo (JP)

(72) Inventor: Yuya MINOURA, Miyagi (JP)

(73) Assignee: Tokyo Electron Limited, Tokyo (JP)

(21) Appl. No.: 19/428,345

(22) Filed: Dec. 22, 2025

Related U.S. Application Data
(63) Continuation of application No. PCT/JP2024/022699, filed on Jun. 24, 2024.

(30) Foreign Application Priority Data
Jul. 7, 2023 (JP) 2023-112422

(51) Int. Cl. H01J 37/32

(52) U.S. Cl. CPC H01J 37/32449; H01J 2237/332

(57) ABSTRACT

The plasma processing method includes a1), a2), and a3). In the a1), the surfaces of components in a chamber are coated with a conductive film by turning a first gas and a second gas into plasma in the chamber. In the a2), the substrate is introduced into the chamber. In the a3), the substrate is processed by turning a third gas into plasma in the chamber in a state where the surfaces of components in the chamber are coated with a conductive film. In addition, the first gas contains at least one of carbon, silicon and germanium, and the second gas contains at least one of boron, nitrogen, phosphorus and arsenic.

### CROSS-REFERENCE TO RELATED APPLICATIONS

This application is a continuation application of International Application No. PCT/JP2024/022699, filed on Jun. 24, 2024 which claims the benefit of priority of the prior Japanese Patent Application No. 2023-112422, filed on Jul. 7, 2023, the entire contents of which are incorporated herein by reference.

### FIELD

Various aspects and embodiments of the present disclosure relate to a plasma processing method and a plasma processing apparatus.

### BACKGROUND

Japanese Laid-open Patent Publication No. 2018-113346 discloses “a plasma processing method including a first film forming process of forming a carbon-containing film on a surface of an internal member of a chamber with plasma of a carbon-containing gas, a second film forming process of forming a silicon-containing film whose thickness is determined according to a thickness of the carbon-containing film, on a surface of the carbon-containing film with a silicon-containing gas, a plasma processing process of performing plasma processing on an object to be processed, which is introduced into the chamber, with plasma of processing gas, a first removal process of removing the silicon-containing film from the surface of the carbon-containing film with plasma of a fluorine-containing gas after the plasma-processed object to be processed is taken out to the outside of the chamber, and a second removal process of removing the carbon-containing film from the surface of the member with plasma of an oxygen-containing gas”.

The present disclosure provides a plasma processing method and a plasma processing apparatus capable of achieving process stabilization while suppressing wear of components in a chamber.

### SUMMARY

According to an aspect of an embodiment, a plasma processing method for processing a substrate using plasma includes a1), a2), and a3). In the a1), the surfaces of components in a chamber are coated with a conductive film by turning a first gas and a second gas into plasma in the chamber. In the a2), the substrate is introduced into the chamber. In the a3), the substrate is processed by turning a third gas into plasma in the chamber in a state where the surface of the component in the chamber is coated with the conductive film. The first gas contains at least one of carbon, silicon and germanium. The second gas contains at least one of boron, nitrogen, phosphorus and arsenic.

### BRIEF DESCRIPTION OF DRAWINGS

FIG. 1 is a schematic diagram illustrating an example of a plasma processing apparatus;

FIG. 2 is a flowchart illustrating an example of a plasma processing method according to a first embodiment;

FIG. 3A is a diagram illustrating an example of a change in direct current passing through a showerhead when the inside of a plasma processing chamber is coated with a protective film that is not conductive;

FIG. 3B is a diagram illustrating an example of a change in direct current passing through a showerhead when the inside of a plasma processing chamber is coated with a conductive protective film that is formed in the present embodiment;

FIG. 4 is a diagram illustrating an example of a relationship between the carrier density and the conductivity of diamond-like carbon;

FIG. 5 is a diagram illustrating an example of a relationship between the impurity concentration and the resistivity of diamond-like carbon;

FIG. 6 is a flowchart illustrating an example of a plasma processing method according to a second embodiment;

FIG. 7 is a flowchart illustrating an example of a plasma processing method according to a third embodiment;

FIG. 8 is a flowchart illustrating an example of a plasma processing method according to a fourth embodiment.

### DESCRIPTION OF EMBODIMENTS

Hereinafter, embodiments of a plasma processing method and a plasma processing apparatus will be described in detail with reference to the drawings. The plasma processing method and the plasma processing apparatus disclosed are not limited by the following embodiments.

In a chamber, there exists an electrode functioning as an anode or a cathode with respect to plasma produced in the chamber. Such an electrode is required to be electrically continuous with plasma for transferring electrons between the electrode and the plasma.

However, if the protective film formed on a surface of a component in a chamber for protecting the component in the chamber is an insulating film, electrical continuity between the plasma and the electrode is deteriorated, so that transfer of electrons between the electrode and the plasma is hindered. As a result, the state of the plasma is different from the design-time state. Thus, the process may become unstable, leading to an increased gap between the result of the process and the desired result.

To address this, the present disclosure provides a technique capable of achieving process stabilization while suppressing wear of components in a chamber.

### First Embodiment

### [Configuration of Plasma Processing Apparatus 1]

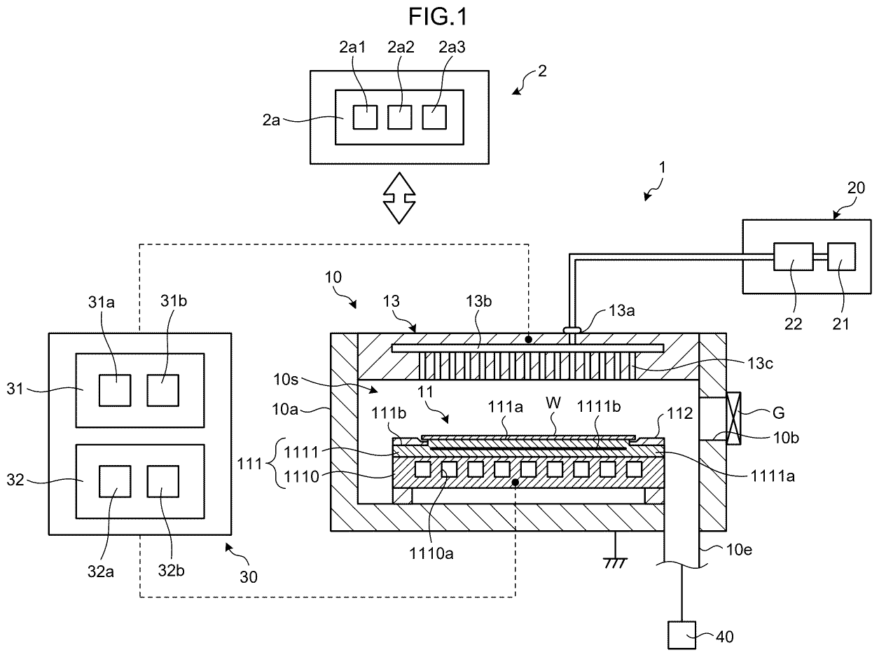

FIG. 1 is a schematic diagram illustrating an example of a plasma processing apparatus 1. In the present embodiment, the plasma processing apparatus 1 is, for example, a capacitively coupled plasma processing apparatus. A plasma processing chamber 10 includes a plasma processing chamber 10, a gas supplier 20, a power supply 30, and an exhaust system 40. The plasma processing apparatus 1 includes a substrate support 11 and a gas introducer. The gas introducer is configured to introduce at least one gas into the plasma processing chamber 10. The gas introducer includes a showerhead 13. The substrate support 11 is disposed in the plasma processing chamber 10. The showerhead 13 is arranged above the substrate support 11. In an embodiment, the showerhead 13 forms at least a part of a ceiling of the plasma processing chamber 10. The plasma processing chamber 10 has a plasma processing space 10s defined by the showerhead 13, a lateral wall 10a of the plasma processing chamber 10, and the substrate support 11.

The plasma processing chamber 10 includes at least one gas supply port for supplying at least one gas to the plasma processing space 10s and at least one gas discharge port for discharging the gas from the plasma processing space. The plasma processing chamber 10 is formed of a conductor such as aluminum and is grounded. The showerhead 13 and the substrate support 11 are electrically insulated from a case of the plasma processing chamber 10. An opening 10b through which a substrate W is introduced into the plasma processing chamber 10 and the substrate W is taken out from the inside of the plasma processing chamber 10 is formed in the lateral wall 10a of the plasma processing chamber 10. The opening 10b is opened and closed by a gate valve G.

The substrate support 11 includes a main body part 111 and a ring assembly 112. The main body part 111 has a central region 111a for supporting the substrate W and a ring-shaped region 111b for supporting the ring assembly 112. The wafer is an example of the substrate W. The ring-shaped region 111b of the main body part 111 surrounds a central region 111a of the main body part 111 in plan view. The substrate W is arranged on the central region 111a of the main body part 111, and the ring assembly 112 is arranged on the ring-shaped region 111b of the main body part 111 so as to surround the substrate W on the central region 111a of the main body part 111. Therefore, the central region 111a is also called a substrate support surface for supporting the substrate W, and the ring-shaped region 111b is also called a ring support surface for supporting the ring assembly 112.

In an embodiment, the main body part 111 includes a base 1110 and an electrostatic chuck 1111. The base 1110 includes a conductive member. The conductive member of the base 1110 can function as a lower electrode. The electrostatic chuck 1111 is arranged on the base 1110. The electrostatic chuck 1111 includes a ceramic member 1111a and an electrostatic electrode 1111b arranged in the ceramic member 1111a. The ceramic member 1111a has a central region 111a. In an embodiment, the ceramic member 1111a also has a ring-shaped region 111b. Another member surrounding the electrostatic chuck 1111, such as a ring-shaped electrostatic chuck or a ring-shaped insulating member, may have the ring-shaped region 111b. Here, the ring assembly 112 may be arranged on the ring-shaped electrostatic chuck or the ring-shaped insulating member, or may be arranged on both the electrostatic chuck 1111 and the ring-shaped insulating member. In addition, at least one RF/DC electrode coupled to a radio frequency (RF) power supply 31 and/or a direct current (DC) power supply 32 described later may be arranged in the ceramic member 1111a. Here, at least one RF/DC electrode functions as a lower electrode. When a bias RF signal and/or DC signal described later is supplied to at least one RF/DC electrode, the RF/DC electrode is also called a bias electrode. The conductive member of the base 1110 and at least one RF/DC electrode may function as a plurality of lower electrodes. In addition, the electrostatic electrode 1111b may function as a lower electrode. Therefore, the substrate support 11 includes at least one lower electrode.

The ring assembly 112 includes one or more ring-shaped members. In an embodiment, one or more ring-shaped members include one or more edge rings and at least one covering. The edge ring is formed of a conductive material or an insulating material, and the covering is formed of an insulating material.

In addition, the substrate support 11 may include a temperature control module configured to adjust at least one of the electrostatic chuck 1111, the ring assembly 112 and the substrate W to a target temperature. The temperature control module may include a heater, a heat transfer medium, a flow channel 1110a, or a combination thereof. Heat transfer fluid such as brine or gas passes through the flow channel 1110a. In an embodiment, a flow channel 1110a is formed in the base 1110, and one or more heaters are arranged in the ceramic member 1111a of the electrostatic chuck 1111. In addition, the substrate support 11 may include a heat transfer gas supplier configured to supply heat transfer gas to a gap between the back surface of the substrate W and the central region 111a.

A through-hole (not illustrated) is formed in the electrostatic chuck 1111 below the central region 111a, and a lift pin (not illustrated) is inserted into the through-hole. The lift pin is vertically moved by an upward-and-downward movement mechanism (not illustrated). The vertical movement of the lift pin can vertically move the substrate W placed on the central region 111a. For example, the gate valve G is opened, and the substrate W is then introduced into the plasma processing chamber 10 through the opening 10b by a transfer robot (not illustrated), and placed on a lift pin whose tip protrudes from the upper surface of the electrostatic chuck 1111. Then, when the lift pin goes down, the substrate W is placed on the electrostatic chuck 1111, the gate valve G is closed, and the substrate W is processed in the plasma processing chamber 10. In addition, in the processed substrate W, the substrate W is lifted from the upper surface of the electrostatic chuck 1111 as the lift pin moves upward. The gate valve G is opened, and the substrate W is then taken out from the inside of the plasma processing chamber 10 through the opening 10b by a transfer robot (not illustrated).

The showerhead 13 is configured to introduce at least one gas from the gas supplier 20 into the plasma processing space 10s. The showerhead 13 includes at least one gas supply port 13a, at least one gas diffusion chamber 13b, and a plurality of gas introduction ports 13c. The gas supplied to the gas supply port 13a is introduced from a plurality of gas introduction ports 13c into the plasma processing space 10s through the gas diffusion chamber 13b. In addition, the showerhead 13 includes at least one upper electrode. The gas introducer may include, in addition to the showerhead 13, one or more side gas injectors (SGI) mounted in one or more openings formed in the lateral wall 10a.

The gas supplier 20 may include at least one gas source 21 and at least one flow control device 22. In an embodiment, the gas supplier 20 is configured to supply at least one gas from the corresponding gas source 21 through the corresponding flow control device 22 to the showerhead 13. Each flow control device 22 may include, for example, a mass flow controller or a flow controller of pressure control type. Further, the gas supplier 20 may include one or more flow modulation devices that modulate or pulse the flow of at least one gas.

The power supply 30 includes an RF power supply 31 coupled to the plasma processing chamber 10 through at least one impedance matching circuit. The RF power supply 31 is configured to supply at least one RF signal (RF power) to the at least one lower electrode and/or the at least one upper electrode. This forms plasma from at least one gas supplied to the plasma processing space 10s.

Therefore, the RF power supply 31 can function as at least a part of a plasma generator configured to produce plasma from one or more gases in the plasma processing chamber 10. In addition, by supplying a bias RF signal to at least one lower electrode, a bias potential is generated in the substrate W, and an ion component in the formed plasma can be drawn into the substrate W.

In an embodiment, the RF power supply 31 includes a first RF producer 31a and a second RF producer 31b. The first RF producer 31a is coupled to at least one lower electrode and/or at least one upper electrode through at least one impedance matching circuit, and configured to produce a source RF signal (source RF power) for plasma production. In an embodiment, the frequency of the source RF signal is within the range of 10 MHz to 150 MHz. In an embodiment, the first RF producer 31a may be configured to produce a plurality of source RF signals having different frequencies. One or more source RF signals produced are supplied to at least one lower electrode and/or at least one upper electrode.

The second RF producer 31b is coupled to at least one lower electrode through at least one impedance matching circuit, and configured to produce a bias RF signal (bias RF power). The frequency of the bias RF signal may be identical to or different from the frequency of the source RF signal. In an embodiment, the bias RF signal has a frequency lower than the frequency of the source RF signal. In an embodiment, the frequency of the bias RF signal is within the range of 100 kHz to 60 MHz. In an embodiment, the second RF producer 31b may be configured to produce a plurality of bias RF signals having different frequencies. One or more bias RF signals produced are supplied to at least one lower electrode. In addition, in various embodiments, at least one of the source RF signal and the bias RF signal may be pulsed.

In addition, the power supply 30 may include a DC power supply 32 coupled to the plasma processing chamber 10. The DC power supply 32 includes a first DC producer 32a and a second DC producer 32b. In an embodiment, the first DC producer 32a is connected to at least one lower electrode, and configured to produce a first DC signal. The first bias DC signal produced is applied to at least one lower electrode. In an embodiment, the second DC producer 32b is connected to at least one upper electrode, and configured to produce a second DC signal. The second DC signal produced is applied to at least one upper electrode.

In various embodiments, at least one of the first and second DC signals may be pulsed. Here, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform producer for producing a sequence of voltage pulses from a DC signal is connected between the first DC producer 32a and at least one lower electrode. Therefore, the first DC producer 32a and the waveform producer form a voltage pulse producer. When the second DC producer 32b and the waveform producer form a voltage pulse producer, the voltage pulse producer is connected to at least one upper electrode. The voltage pulse may have a positive polarity or a negative polarity. In addition, the sequence of voltage pulses may include one or more positive polarity voltage pulses and one or more negative polarity voltage pulses within one period. The first and second DC producers 32a and 32b may be provided in addition to the RF power supply 31, or the first DC producer 32a may be provided in place of the second RF producer 31b.

The exhaust system 40 can be connected to, for example, a gas discharge port 10e provided at the bottom part of the plasma processing chamber 10. The exhaust system 40 may include a pressure adjustment valve and a vacuum pump. The pressure in the processing space 10s is adjusted by the pressure adjustment valve. The vacuum pump may include a turbomolecular pump, a dry pump, or a combination thereof.

A controller 2 handles a computer-executable instruction that causes the plasma processing apparatus 1 to execute various processes described in the present disclosure. The controller 2 can be configured to control each element of the plasma processing apparatus 1 so that various processes described herein are executed. In an embodiment, the plasma processing apparatus 1 may include a part or all of the controller 2. The controller 2 may include a processor 2a1, a storage 2a2, and a communication interface 2a3. The controller 2 is implemented by, for example, a computer 2a. The processor 2a1 can be configured to read a program from the storage 2a2, and execute the read program, thereby performing various control operations. This program may be stored in the storage 2a2 in advance, or may be acquired through a medium when necessary. The acquired program is stored in the storage 2a2, and read from the storage 2a2 and executed by the processor 2a1. The medium may be a storage medium of every kind which can be read by the computer 2a, or a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 communicates with the plasma processing apparatus 1 through a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

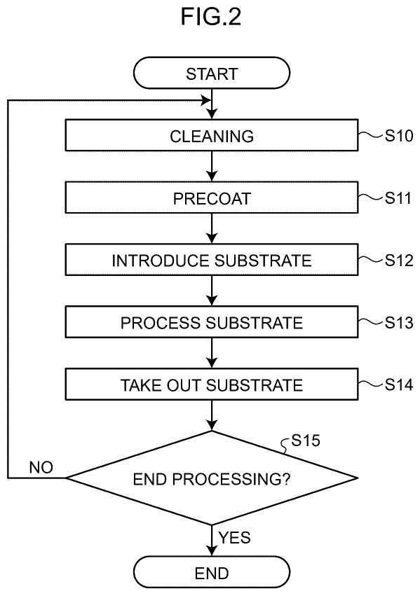

FIG. 2 is a flowchart illustrating an example of a plasma processing method according to the first embodiment. The plasma processing method illustrated in FIG. 2 is implemented by the controller 2 controlling the units of the plasma processing apparatus 1.

First, the inside of the plasma processing chamber 10 is cleaned (step S10). In step S10, a cleaning gas is supplied from the gas supplier 20 into the plasma processing chamber 10 through the showerhead 13, and the cleaning gas is turned into plasma by RF power supplied from the power supply 30 into the plasma processing chamber 10. Deposits on the surfaces of components in the plasma processing chamber 10 are removed by, for example, active species contained in the plasma.

Next, pre-coating for forming a protective film on the surfaces of components in the plasma processing chamber 10 is performed (step S11). Step S11 is an example of step a1). In step S11, a first gas and a second gas are supplied from the gas supplier 20 into the plasma processing chamber 10 through the showerhead 13. In the plasma processing chamber 10, the first gas and the second gas are turned into plasma by the RF power supplied from the power supply 30 into the plasma processing chamber 10. In this way, a conductive protective film is formed on the surfaces of components in the plasma processing chamber 10. In step S11, a protective film is formed on the surfaces of components in the plasma processing chamber 10 by plasma enhanced-chemical vapor deposition (PE-CVD).

In the present embodiment, the first gas contains at least one of carbon, silicon and germanium. When the first gas contains carbon, the first gas contains, for example, at least one of hydrocarbon gas, hydrofluorocarbon gas, fluorocarbon gas and carbon tetrachloride gas. When the first gas contains silicon, the first gas contains, for example, at least one of aminosilane gas, monosilane gas, disilane gas, dichlorosilane gas, silicon tetrachloride gas and silicon tetrafluoride gas. When the first gas contains germanium, the first gas contains, for example, at least one of monogermane gas and germanium tetrachloride gas.

In the present embodiment, the second gas contains at least one of boron, nitrogen, phosphorus and arsenic. When the second gas contains boron, the second gas contains, for example, at least one of boron trifluoride gas, boron trichloride gas, monoborane gas, diborane gas and boron tribromide gas. When the second gas contains nitrogen, the second gas contains, for example, at least one of nitrogen gas, ammonia gas, nitrogen trifluoride gas, nitrogen trichloride gas, nitrogen monoxide gas, nitrous oxide gas, nitrogen dioxide gas and trimethylamine gas. When the second gas contains phosphorus, the second gas contains, for example, at least one of phosphorus trifluoride gas, phosphorus trichloride gas, phosphine gas, phosphorus pentafluoride gas, phosphorus pentachloride gas, phosphorus tribromide gas and phosphoryl chloride gas. When the second gas contains arsenic, the second gas contains, for example, at least one of arsine gas, arsenic trifluoride gas, arsenic pentafluoride gas, arsenic trichloride gas and arsenic pentachloride gas.

In step S11, an inert gas such as a rare gas may be added in addition to the first gas and the second gas.

In addition, in the example of FIG. 2, the first gas and the second gas turned into plasma form a protective film in a state where the inside of the plasma processing chamber 10 is supplied with both the first gas and the second gas in step S11, but the technique of the disclosure is not limited thereto. As another form, in step S11, a protective film may be formed by two steps. For example, in a first step, a first gas is supplied into the plasma processing chamber 10, and a protective film that is not conductive is formed by the first gas turned into plasma.

Subsequently, in a second step, a second gas is supplied into the plasma processing chamber 10, and the second gas is turned into plasma. Accordingly, boron atoms and the like contained in the plasma produced from the second gas are added to the protective film formed in the first step, and the protective film formed in the first step is reformed into a conductive protective film. Even in this way, a conductive protective film can be formed in step S11. The first step and the second step may be alternately repeated two or more times.

The explanation will be continued by returning to FIG. 2. Next, the substrate W is introduced into the plasma processing chamber 10 (step S12). Step S12 is an example of process a2). In step S12, the controller 2 controls a lift pin driving mechanism (not illustrated) so that the tip of a lift pin (not illustrated) protrudes from the upper surface of the electrostatic chuck 1111. The controller 2 controls the gate valve G so as to open the gate valve G. The substrate W is introduced into the plasma processing chamber 10 by a transfer robot (not illustrated) through the opening 10b, and placed on the lift pin. Then, the controller 2 controls the lift pin driving mechanism so that the lift pin goes down. Accordingly, the lift pin goes down, and the substrate W is placed on the electrostatic chuck 1111. The controller 2 controls the gate valve G so as to close the gate valve G.

Next, the substrate W is processed with plasma (step S13). Step S13 is an example of process a3). In step S13, a third gas is supplied from the gas supplier 20 into the plasma processing chamber 10 through the showerhead 13. In the plasma processing chamber 10, the third gas is turned into plasma by the RF power for plasma production which is supplied from the power supply 30 into the plasma processing chamber 10. In addition, RF power for biasing and a DC signal are supplied from the power supply 30 into the plasma processing chamber 10 as necessary. Processing such as film formation and etching is performed on the substrate W by active species and ions contained in the plasma. In step S13, reaction by-products (so-called deposits) generated due to the processing of the substrate W attach to the surface of the protective film formed on the surfaces of components in the plasma processing chamber 10 in step S11.

In the present embodiment, when the substrate W is etched, a gas capable of etching a film to be etched, which the substrate W has, is used as the third gas. When the film to be etched is a silicon oxide film or a silicon nitride film, the third gas contains fluorocarbon gas or hydrofluorocarbon gas. When the film to be etched is a silicon film or a metal film, the third gas contains a halogen-containing gas. When the film to be etched is an organic film, the third gas contains an oxygen-containing gas and a hydrogen-containing gas.

Next, the substrate W is taken out from the inside of the plasma processing chamber 10 (step S14). In step S14, the controller 2 controls a lift pin driving mechanism so that the tip of a lift pin protrudes from the upper surface of the electrostatic chuck 1111.

Accordingly, the processed substrate W is lifted from the electrostatic chuck 1111. The controller 2 controls the gate valve G so as to open the gate valve G. The processed substrate W is then taken out from the plasma processing chamber 10 through the opening 10b by a transfer robot (not illustrated). The controller 2 controls the gate valve G so as to close the gate valve G, and controls the lift pin driving mechanism so that the lift pin goes down.

Next, the controller 2 judges whether or not processing of the substrates W is to be ended (step S15). When processing of the substrate W is not ended (step S15: No), the controller 2 executes the process of step S10 again. On the other hand, when processing of the substrate W is ended (step S15: Yes), the controller 2 ends the plasma processing method illustrated in the present flowchart.

In the cleaning performed in the second and subsequent steps S10, the protective film formed on the surfaces of components in the plasma processing chamber 10 in step S11 and deposits attached on the surface of the protective film in step S13 are removed. When both the protective film and the deposit are carbon-containing films, for example, an oxygen-containing gas is used as the cleaning gas in the second and subsequent steps S10. In addition, when both the protective film and the deposit are silicon- or germanium-containing films, for example, a gas containing a halogen element such as fluorine or chlorine is used as the cleaning gas in the second and subsequent steps S10.

In addition, when the protective film is a carbon-containing film and the deposit is a silicon- or germanium-containing film, cleaning is performed using, for example, a gas containing a halogen element, and cleaning is then performed using, for example, an oxygen-containing gas, in the second and subsequent steps S10. In addition, when the protective film is a silicon- or germanium-containing film and the deposit is a carbon-containing film, cleaning is performed using, for example, an oxygen-containing gas, and cleaning is then performed using, for example, a gas containing a halogen element, in the second and subsequent steps S10. In addition, when one of the protective film and the deposit is a carbon-containing film and the other is a silicon- or germanium-containing film, cleaning may be performed using, for example, a gas containing both an oxygen-containing gas and a gas containing a halogen element, in the second and subsequent steps S10.

In steps S10 and S11, for protecting the surface of the electrostatic chuck 1111, a dummy substrate differing from the substrate W may be introduced into the plasma processing chamber 10 and taken out after processing in each step. In addition, when processing is continuously performed using the same dummy substrate in steps S10 and S11, the dummy substrate may be introduced before step S10, and taken out after step S11.

### [Experimental Results]

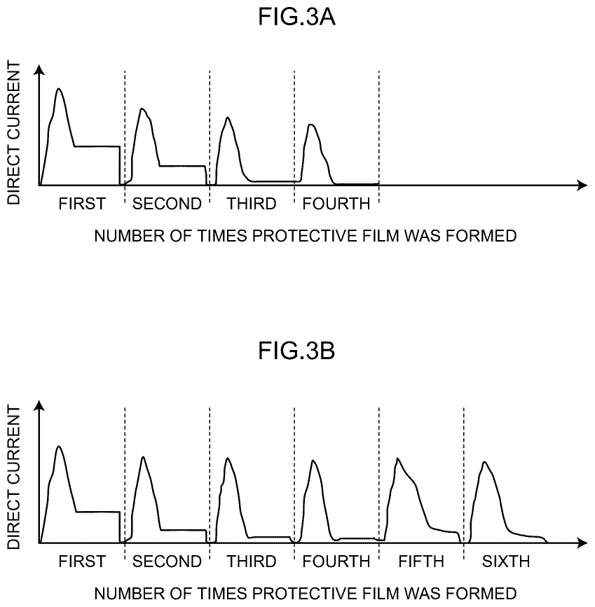

Next, a change in direct current passing through the showerhead 13 with respect to the thickness of the protective film formed on the showerhead 13 was examined. FIG. 3A is a diagram illustrating an example of a change in direct current passing through the showerhead 13 when the inside of the plasma processing chamber 10 is coated with a protective film that is not conductive. In the experiment of FIG. 3A, on a one-by-one basis, a 100 nm protective film that is not conductive was formed, plasma was then produced in the plasma processing chamber 10 while a direct-current voltage was applied to the showerhead 13, and a change in direct current passing through the showerhead 13 was examined. In the case where the protective film was not conductive, a direct current did not pass through the showerhead 13 when a protective film having a thickness of 500 nm or more was formed as illustrated in, for example, FIG. 3A. That is, in the case of a protective film that is not conductive, a direct current does not pass into plasma through the showerhead 13.

FIG. 3B is a diagram illustrating an example of a change in direct current passing through the showerhead 13 when the inside of the plasma processing chamber 10 is coated with a conductive protective film that is formed in the present embodiment. In the experiment of FIG. 3B, on a one-by-one basis, a 100 nm conductive protective film was formed, plasma was then produced in the plasma processing chamber 10 while a direct-current voltage was applied to the showerhead 13, and a change in direct current passing through the showerhead 13 was examined. In the case where the protective film was conductive, a direct current passed through the showerhead 13 even when a protective film having a thickness of 600 nm or more was formed as illustrated in, for example, FIG. 3B. That is, in the case of a conductive protective film, a direct current can be made to pass into plasma through the showerhead 13.

### [Impurity Added to Protective Film]

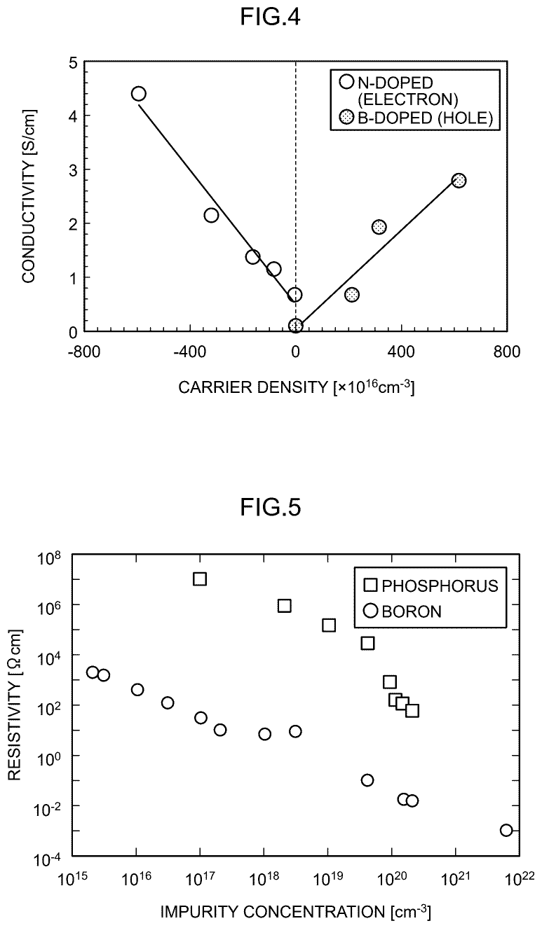

FIG. 4 is a diagram illustrating an example of a relationship between the carrier density and the conductivity of diamond-like carbon. When the protective film is diamond-like carbon, the conductivity of the protective film is almost 0 as illustrated in, for example, FIG. 4 when N (nitrogen) atoms or B (boron) atoms are not added. On the other hand, with an increase in amount of N (nitrogen) atoms or B (boron) atoms added, the conductivity of the protective film increases as illustrated in, for example, FIG. 4.

FIG. 5 is a diagram illustrating an example of a relationship between the impurity concentration and the resistivity of diamond-like carbon. When phosphorus or boron is added as an impurity to a protective film of diamond-like carbon, the resistivity of the protective film decreases with an increase in concentration of the impurity as illustrated in, for example, FIG. 5. That is, with an increase in concentration of the impurity, the conductivity of the protective film increases. In a film of silicon or germanium that is an element of Group 14 to which carbon also belongs, the same characteristics as in FIGS. 4 and 5 are observed. In addition, regarding the impurity added, not only nitrogen, boron and phosphorus, but also arsenic that is an element of Group 15 to which nitrogen and phosphorus also belong can enhance conductivity as in FIGS. 4 and 5 when added to a film of carbon or the like.

In the present embodiment, the protective film is formed by turning the first gas and the second gas into plasma. A film containing at least one of carbon, silicon and germanium is formed by plasma produced from the first gas. Plasma produced from the second gas adds at least one of boron, nitrogen, phosphorus and arsenic to a film formed by the first gas. Accordingly, conductivity is imparted to a film containing at least one of carbon, silicon and germanium.

The first embodiment has been described above. As described above, the plasma processing method according to the present embodiment is a plasma processing method in which a substrate is processed using plasma, the method including process a1), process a2), and process a3). In process a1), the surfaces of components in a chamber (plasma processing chamber 10) are coated with a conductive film by turning a first gas and a second gas into plasma in the chamber. In process a2), the substrate is introduced into the chamber. In process a3), the substrate is processed by turning a third gas in the chamber in a state where the surfaces of components in the chamber are coated with a conductive film. In addition, the first gas contains at least one of carbon, silicon and germanium, and the second gas contains at least one of boron, nitrogen, phosphorus and arsenic. As a result, process stabilization can be achieved while wear of components in the plasma processing chamber 10 is suppressed.

In addition, in the embodiment described above, the surfaces of components in the chamber are coated with a conductive film by turning the first gas and the second gas into plasma in the chamber in a state where the inside of the chamber are supplied with both the first gas and the second gas in process a1). Accordingly, the protective film can be easily formed.

In addition, in the embodiment described above, the surfaces of components in the chamber are coated with a conductive film by turning the second gas into plasma after turning the first gas into plasma in the chamber in process a1). Accordingly, the protective film can be easily formed.

In addition, in the embodiment described above, the first gas contains at least one of hydrocarbon gas, hydrofluorocarbon gas, fluorocarbon gas and carbon tetrachloride gas. Alternatively, the first gas contains at least one of aminosilane gas, monosilane gas, disilane gas, dichlorosilane gas, silicon tetrachloride gas and silicon tetrafluoride gas. Alternatively, the first gas contains at least one of monogermane gas and germanium tetrachloride gas. Accordingly, the protective film can be easily formed.

In the embodiment described above, when, among aminosilane gases, a gas that has high reactivity even without being turned into plasma, such as HMDS (hexamethyldisilazane), among aminosilane gases is used as the first gas, the surfaces of components in the chamber may be coated with a conductive film by introducing the first gas into the chamber, attaching the first gas to the surfaces of components in the chamber, and then turning the second gas into plasma in process a1).

In addition, in the embodiment described above, the second gas contains at least one of boron trifluoride gas, boron trichloride gas, monoborane gas, diborane gas and boron tribromide gas. Alternatively, the second gas contains at least one of nitrogen gas, ammonia gas, nitrogen trifluoride gas, nitrogen trichloride gas, nitrogen monoxide gas, nitrous oxide gas, nitrogen dioxide gas and trimethylamine gas. Alternatively, the second gas contains at least one of phosphorus trifluoride gas, phosphorus trichloride gas, phosphine gas, phosphorus pentafluoride gas, phosphorus pentachloride gas, phosphorus tribromide gas and phosphoryl chloride gas. Alternatively, the second gas contains at least one of arsine gas, arsenic trifluoride gas, arsenic pentafluoride gas, arsenic trichloride gas and arsenic pentachloride gas. Accordingly, the protective film can be easily formed.

In addition, the plasma processing apparatus (plasma processing apparatus 1) according to the embodiment described above includes a chamber (plasma processing chamber 10) having a gas supply port and a gas discharge port, a substrate support (substrate support 11) that is provided in the chamber and supports the substrate, a plasma generator (RF power supply 31) that produces plasma from the gas supplied into the chamber, and a controller (controller 2). The controller executes process a1), process a2), and process a3). In process a1), the surfaces of components in a chamber (plasma processing chamber 10) are coated with a conductive film by turning a first gas and a second gas into plasma in the chamber. In process a2), the substrate introduced into the chamber is placed on the substrate support. In process a3), the substrate is processed by turning a third gas into plasma in the chamber in a state where the surfaces of components in the chamber are coated with a conductive film. In addition, the first gas contains at least one of carbon, silicon and germanium, and the second gas contains at least one of boron, nitrogen, phosphorus and arsenic. As a result, process stabilization can be achieved while wear of components in the plasma processing chamber 10 is suppressed.

### Second Embodiment

In the first embodiment, a conductive protective film is formed on the surfaces of components in the plasma processing chamber 10 by PE-CVD.

On the other hand, in the present embodiment, a conductive protective film is formed on the surfaces of components in a plasma processing chamber 10 by sputtering. Hereinafter, the second embodiment will be described with an emphasis on differences from the first embodiment. The configuration of a plasma processing apparatus 1 is similar to that of the plasma processing apparatus 1 according to the first embodiment, and therefore will not be explained.

### [Plasma Processing Method]

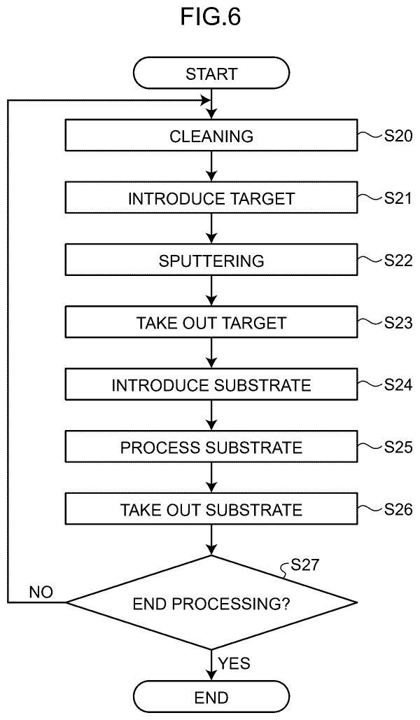

FIG. 6 is a flowchart illustrating an example of a plasma processing method according to the second embodiment. The plasma processing method illustrated in FIG. 6 is implemented by controlling of the units of the plasma processing apparatus 1 by the controller 2.

First, the inside of the plasma processing chamber 10 is cleaned (step S20). A target is introduced into the plasma processing chamber 10 (step S21). Step S21 is an example of process b1) and process c1). The target contains an element that is at least one of carbon, silicon and germanium. In the present embodiment, a substrate W′ on which the target is arranged is introduced into the plasma processing chamber 10, and placed on an electrostatic chuck 1111. As long as the target is arranged in the plasma processing chamber 10, it may be arranged in the plasma processing chamber 10 in a form other than the substrate W′, for example, in the form of an edge ring in which the target is arranged.

Next, sputtering is performed in the plasma processing chamber 10 (step S22). Step S22 is an example of process b2). In step S22, a rare gas and an additive gas are supplied from a gas supplier 20 into the plasma processing chamber 10 through a showerhead 13. In the plasma processing chamber 10, the rare gas and the additive gas are turned into plasma by the RF power for plasma production which is supplied from a power supply 30 into the plasma processing chamber 10. In addition, RF power for biasing and a DC signal are supplied from the power supply 30 into the plasma processing chamber 10 as necessary. Atoms contained in the target are driven out by ions contained in the plasma, and deposited as a protective film on the surfaces of components in the plasma processing chamber 10. In addition, an element of the additive gas contained in the plasma is added to the protective film. In this way, a conductive protective film is formed on the surfaces of components in the plasma processing chamber 10.

The additive gas in step S22 contains at least one of boron, nitrogen, phosphorus and arsenic. When the additive gas contains boron, the additive gas contains, for example, at least one of boron trifluoride gas, boron trichloride gas, monoborane gas, diborane gas and boron tribromide gas. When the additive gas contains nitrogen, the additive gas contains, for example, at least one of nitrogen gas, ammonia gas, nitrogen trifluoride gas, nitrogen trichloride gas, nitrogen monoxide gas, nitrous oxide gas, nitrogen dioxide gas and trimethylamine gas.

When the additive gas contains phosphorus, the additive gas contains, for example, at least one of phosphorus trifluoride gas, phosphorus trichloride gas, phosphine gas, phosphorus pentafluoride gas, phosphorus pentachloride gas, phosphorus tribromide gas and phosphoryl chloride gas. When the additive gas contains arsenic, the additive gas contains, for example, at least one of arsine gas, arsenic trifluoride gas, arsenic pentafluoride gas, arsenic trichloride gas and arsenic pentachloride gas.

Next, the target is taken out from the inside of the plasma processing chamber 10 (step S23). The substrate W is introduced into the plasma processing chamber 10 (step S24). Step S24 is an example of process b3), process c4) and process d3). The substrate W is processed with plasma (step S25). Step S25 is an example of process b4), process c5) and process d4). The substrate W is taken out from the inside of the plasma processing chamber 10 (step S26).

Next, the controller 2 judges whether or not processing of the substrates W is to be ended (step S27). When processing of the substrate W is not ended (step S27: No), the controller 2 executes the process of step S20 again. On the other hand, when processing of the substrate W is ended (step S27: Yes), the controller 2 ends the plasma processing method illustrated in the present flowchart.

In addition, after the target is taken out from the inside of the plasma processing chamber 10 in step S23, reforming processing for a protective film may be performed as in step S31 described later in a third embodiment. Accordingly, a protective film having higher conductivity is formed.

In the cleaning performed in the second and subsequent steps S20, the protective film formed on the surfaces of components in the plasma processing chamber 10 in step S22 and deposits attached on the surface of the protective film in step S25 are removed. When both the protective film and the deposit are carbon-containing films, for example, an oxygen-containing gas is used as the cleaning gas in the second and subsequent steps S20. In addition, when both the protective film and the deposit are silicon- or germanium-containing films, for example, a gas containing a halogen element such as fluorine or chlorine is used as the cleaning gas in the second and subsequent steps S20.

In addition, when the protective film is a carbon-containing film, and the deposit is a silicon- or germanium-containing film, cleaning is performed using, for example, a gas containing a halogen element, and cleaning is then performed using, for example, an oxygen-containing gas, in the second and subsequent steps S20. In addition, when the protective film is a silicon- or germanium-containing film and the deposit is a carbon-containing film, cleaning is performed using, for example, an oxygen-containing gas, and cleaning is then performed using, for example, a gas containing a halogen element, in the second and subsequent steps S20. In addition, when one of the protective film and the deposit is a carbon-containing film and the other is a silicon- or germanium-containing film, cleaning may be performed using, for example, a gas containing both an oxygen-containing gas and a gas containing a halogen element, in the second and subsequent steps S20.

In steps S20 and S11, for protecting the surface of the electrostatic chuck 1111, a dummy substrate differing from the substrate W may be introduced into the plasma processing chamber 10 and taken out after processing. The dummy substrate may be a substrate W′ on which the target for use in step S22 is arranged. Here, the substrate W′ may be introduced into the chamber before step S20, with the substrate W′ taken out after step S11.

The second embodiment has been described above. As described above, the plasma processing method according to the present embodiment is a plasma processing method in which a substrate is processed using plasma, the method including process b1), process b2), process b3), and process b4). In process b1), a target containing a predetermined element is arranged in the chamber (plasma processing chamber 10). In process b2), the surfaces of components in the chamber are coated with a conductive film by turning a rare gas and an additive gas into plasma to sputter the target in the chamber. In process b3), the substrate is introduced into the chamber. In process b4), the substrate is processed by turning a processing gas into plasma in the chamber in a state where the surfaces of components in the chamber are coated with a conductive film. In addition, the element contained in the target is at least one of carbon, silicon and germanium, and the additive gas contains at least one of boron, nitrogen, phosphorus and arsenic. As a result, process stabilization can be achieved while wear of components in the plasma processing chamber 10 is suppressed.

In addition, the plasma processing apparatus (plasma processing apparatus 1) according to the embodiment described above includes a chamber (plasma processing chamber 10) having a gas supply port and a gas discharge port, a substrate support (substrate support 11) that is provided in the chamber and supports the substrate, a plasma generator (RF power supply 31) that produces plasma from the gas supplied into the chamber, and a controller (controller 2). The controller executes process b1), process b2), process b3), and process b4). In process b1), a target containing a predetermined element is arranged in the chamber. In process b2), the surfaces of components in the chamber are coated with a conductive film by turning a rare gas and an additive gas into plasma to sputter the target in the chamber. In process b3), the substrate introduced into the chamber is placed on the substrate support. In process b4), the substrate is processed by turning a processing gas into plasma in the chamber in a state where the surfaces of components in the chamber are coated with a conductive film. In addition, the element contained in the target is at least one of carbon, silicon and germanium, and the additive gas contains at least one of boron, nitrogen, phosphorus and arsenic. As a result, process stabilization can be achieved while wear of components in the plasma processing chamber 10 is suppressed.

### Third Embodiment

In the second embodiment, a protective film is formed by sputtering using a rare gas and an additive gas turned into plasma. On the other hand, in the present embodiment, a protective film that is not conductive is formed using a rare gas turned into plasma, and the protective film is then reformed into a conductive protective film using a reforming gas turned into plasma.

Hereinafter, the third embodiment will be described with an emphasis on differences from the second embodiment. The configuration of a plasma processing apparatus 1 is similar to that of the plasma processing apparatus 1 according to the first embodiment, and therefore will not be explained.

### [Plasma Processing Method]

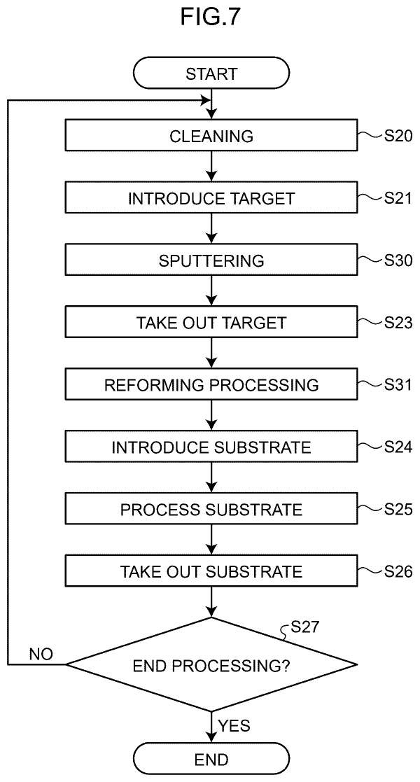

FIG. 7 is a flowchart illustrating an example of a plasma processing method according to the third embodiment. Processes denoted by reference numerals identical to those in FIG. 6, in the flowchart illustrated in FIG. 7, are similar to the processes described with reference to FIG. 6, and therefore will not be explained.

After the target is introduced into the plasma processing chamber 10 in step S21, sputtering is performed in the plasma processing chamber 10 (step S30). Step S30 is an example of process c2). In step S30, a rare gas is supplied from the gas supplier 20 into the plasma processing chamber 10 through the showerhead 13. In the plasma processing chamber 10, the rare gas is turned into plasma by the RF power for plasma production which is supplied from the power supply 30 into the plasma processing chamber 10. In addition, RF power for biasing and a DC signal are supplied from the power supply 30 into the plasma processing chamber 10 as necessary. Atoms contained in the target are driven out by ions contained in the plasma, and a protective film that is not conductive is formed on the surfaces of components in the plasma processing chamber 10. The target is taken out from the inside of the plasma processing chamber 10 (step S23).

Next, reforming processing for the protective film is performed (step S31). Step S31 is an example of process c3). In step S31, a reforming gas is supplied from the gas supplier 20 into the plasma processing chamber 10 through the showerhead 13. In the plasma processing chamber 10, the reforming gas is turned into plasma by the RF power for plasma production which is supplied from the power supply 30 into the plasma processing chamber 10. In addition, RF power for biasing and a DC signal are supplied from the power supply 30 into the plasma processing chamber 10 as necessary. The protective film that is formed on the surfaces of components in the plasma processing chamber 10 and is not conductive is reformed into a conductive protective film by, for example, active species contained in the plasma. Processing in and after step S24 is performed.

The reforming gas in step S31 contains at least one of boron, nitrogen, phosphorus and arsenic. When the reforming gas contains boron, the reforming gas contains, for example, at least one of boron trifluoride gas, boron trichloride gas, monoborane gas, diborane gas and boron tribromide gas. When the reforming gas contains nitrogen, the reforming gas contains, for example, at least one of nitrogen gas, ammonia gas, nitrogen trifluoride gas, nitrogen trichloride gas, nitrogen monoxide gas, nitrous oxide gas, nitrogen dioxide gas and trimethylamine gas. When the reforming gas contains phosphorus, the reforming gas contains, for example, at least one of phosphorus trifluoride gas, phosphorus trichloride gas, phosphine gas, phosphorus pentafluoride gas, phosphorus pentachloride gas, phosphorus tribromide gas and phosphoryl chloride gas. When the reforming gas contains arsenic, the reforming gas contains, for example, at least one of arsine gas, arsenic trifluoride gas, arsenic pentafluoride gas, arsenic trichloride gas and arsenic pentachloride gas.

In step S31, for protecting the surface of the electrostatic chuck 1111, a dummy substrate differing from the substrate W and the substrate W′ may be introduced into the plasma processing chamber 10 and taken out after processing. The dummy substrate may be a substrate W′ on which the target for use in step S30 is arranged. Here, step S31 is performed before step S23 in which the target is taken out.

In performing sputtering in step S30, an additive gas may be supplied together with the rare gas. The additive gas contains at least one of boron, nitrogen, phosphorus and arsenic. Accordingly, a protective film having higher conductivity is formed.

The third embodiment has been described above. As described above, the plasma processing method according to the present embodiment is a plasma processing method in which a substrate is processed using plasma, the method including process c1), process c2), process c3), process c4) and process c5). In process c1), a target containing a predetermined element is arranged in the chamber (plasma processing chamber 10). In process c2), the surfaces of components in the chamber are coated with a film containing a predetermined element by turning a rare gas into plasma to sputter the target in the chamber. In process c3), the film applied to the surfaces of components in the chamber and containing a predetermined element is reformed into a conductive film by turning the reforming gas into plasma in the chamber. In process c4), the substrate is introduced into the chamber. In process c5), the substrate is processed by turning a process gas into plasma in the chamber in a state where the surfaces of components in the chamber are coated with a conductive film. In addition, the element contained in the target is at least one of carbon, silicon and germanium, and the reforming gas contains at least one of boron, nitrogen, phosphorus and arsenic. As a result, process stabilization can be achieved while wear of components in the plasma processing chamber 10 is suppressed.

In addition, the plasma processing apparatus (plasma processing apparatus 1) according to the embodiment described above includes a chamber (plasma processing chamber 10) having a gas supply port and a gas discharge port, a substrate support (substrate support 11) that is provided in the chamber and supports the substrate, a plasma generator (RF power supply 31) that produces plasma from the gas supplied into the chamber, and a controller (controller 2). The controller executes process c1), process c2), process c3), process c4) and process c5). In process c1), a target containing a predetermined element is arranged in the chamber (plasma processing chamber 10). In process c2), the surfaces of components in the chamber are coated with a film containing a predetermined element by turning a rare gas into plasma to sputter the target in the chamber. In process c3), the film applied to the surfaces of components in the chamber and containing a predetermined element is reformed into a conductive film by turning the reforming gas into plasma in the chamber. In process c4), the substrate introduced into the chamber is placed on the substrate support. In process c5), the substrate is processed by turning a process gas into plasma in the chamber in a state where the surfaces of components in the chamber are coated with a conductive film. In addition, the element contained in the target is at least one of carbon, silicon and germanium, and the reforming gas contains at least one of boron, nitrogen, phosphorus and arsenic. As a result, process stabilization can be achieved while wear of components in the plasma processing chamber 10 is suppressed.

### Fourth Embodiment

In the second embodiment, sputtering using a rare gas and an additive gas turned into plasma is performed on a target containing an element that is at least one of carbon, silicon and germanium, thereby forming a conductive protective film on the surfaces of components in the plasma processing chamber 10. The additive gas contains at least one of boron, nitrogen, phosphorus and arsenic. On the other hand, in the present embodiment, sputtering using a rare gas turned into plasma is performed on a target containing an element that is at least one of carbon, silicon and germanium and an element that is at least one of boron, nitrogen, phosphorus and arsenic, thereby forming a conductive protective film on the surfaces of components in a plasma processing chamber 10. Hereinafter, the fourth embodiment will be described with an emphasis on differences from the second embodiment. The configuration of a plasma processing apparatus 1 is similar to that of the plasma processing apparatus 1 according to the first embodiment, and therefore will not be explained.

### [Plasma Processing Method]

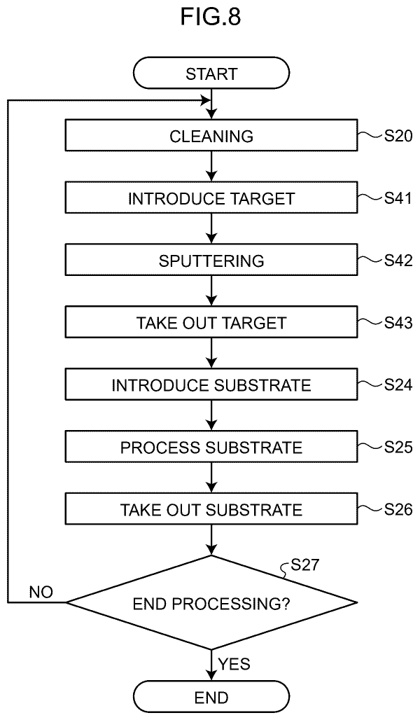

FIG. 8 is a flowchart illustrating an example of a plasma processing method according to the fourth embodiment. The plasma processing method illustrated in FIG. 8 is implemented by controlling of the units of the plasma processing apparatus 1 by the controller 2. Processes denoted by reference numerals identical to those in FIG. 6, in the flowchart illustrated in FIG. 8, are similar to the processes described with reference to FIG. 6, and therefore will not be explained.

After cleaning of the inside of a plasma processing chamber 10 is performed in step S20, the target is introduced into the plasma processing chamber 10 (step S41). Step S41 is an example of process d1). The target contains a first element that is at least one of carbon, silicon and germanium, and a second element that is at least one of boron, nitrogen, phosphorus and arsenic. In the present embodiment, a substrate W″ on which the target is arranged is introduced into the plasma processing chamber 10, and placed on an electrostatic chuck 1111. As long as the target is arranged in the plasma processing chamber 10, it may be arranged in the plasma processing chamber 10 in a form other than the substrate W″, for example, in the form of an edge ring in which the target is arranged.

Next, sputtering is performed in the plasma processing chamber 10 (step S42). Step S42 is an example of process d2). In step S42, a rare gas is supplied from the gas supplier 20 into the plasma processing chamber 10 through the showerhead 13. In the plasma processing chamber 10, the rare gas is turned into plasma by the RF power for plasma production which is supplied from the power supply 30 into the plasma processing chamber 10. In addition, RF power for biasing and a DC signal are supplied from the power supply 30 into the plasma processing chamber 10 as necessary. The first element and the second element contained in the target are driven out by ions contained in the plasma, and a conductive protective film is formed on the surfaces of components in the plasma processing chamber 10. The target is taken out from the inside of the plasma processing chamber 10 (step S43). Processing in and after step S24 is performed.

In sputtering in step S42, an additive gas may be supplied together with the rare gas. The additive gas contains at least one of boron, nitrogen, phosphorus and arsenic. Accordingly, a protective film having higher conductivity is formed.

In addition, after the target is taken out from the inside of the plasma processing chamber 10 in step S43, reforming processing for a protective film may be performed as in step S31 in the third embodiment. Accordingly, a protective film having higher conductivity is formed.

The fourth embodiment has been described above. As described above, the plasma processing method according to the present embodiment is a plasma processing method in which a substrate is processed using plasma, the method including process d1), process d2), process d3), and process d4). In process d1), a target containing a predetermined first element and second element is arranged in the chamber (plasma processing chamber 10). In process d2), the surfaces of components in the chamber are coated with a conductive film by turning a rare gas into plasma to sputter the target in the chamber. In process d3), the substrate is introduced into the chamber. In process d4), the substrate is processed by turning a process gas into plasma in the chamber in a state where the surfaces of components in the chamber are coated with a conductive film. In addition, the first element contained in the target is at least one of carbon, silicon and germanium, and the second element is at least one of boron, nitrogen, phosphorus and arsenic. As a result, process stabilization can be achieved while wear of components in the plasma processing chamber 10 is suppressed.

In addition, the plasma processing apparatus (plasma processing apparatus 1) according to the fourth embodiment described above includes a chamber (plasma processing chamber 10) having a gas supply port and a gas discharge port, a substrate support (substrate support 11) that is provided in the chamber and supports the substrate, a plasma generator (RF power supply 31) that produces plasma from the gas supplied into the chamber, and a controller (controller 2). The controller executes process d1), process d2), process d3), and process d4). In process d1), a target containing a predetermined first element and second element is arranged in the chamber. In process d2), the surfaces of components in the chamber are coated with a conductive film by turning a rare gas into plasma to sputter the target in the chamber. In process d3), the substrate introduced into the chamber is placed on the substrate support. In process d4), the substrate is processed by turning a process gas into plasma in the chamber in a state where the surfaces of components in the chamber are coated with a conductive film. In addition, the first element contained in the target is at least one of carbon, silicon and germanium, and the second element is at least one of boron, nitrogen, phosphorus and arsenic.

As a result, process stabilization can be achieved while wear of components in the plasma processing chamber 10 is suppressed.

### [Others]

The technique disclosed in the present application is not limited to the embodiments described above, and various modifications can be made within the scope of the gist thereof.

For example, in the embodiments described above, the plasma processing apparatus 1 that performs processing using capacitively coupled plasma (CCP) has been described as an example of a plasma source, but the plasma source is not limited to capacitively coupled plasma. Examples of the plasma source other than capacitively coupled plasma include inductively coupled plasma (ICP), microwave-excited surface wave plasma (SWP), electron cyclotron resonance plasma (ECP), and helicon wave-excited plasma (HWP).

According to various aspects and embodiments of the present disclosure, process stabilization can be achieved while wear of components in a chamber is suppressed.

In addition, it should be considered that the embodiments disclosed herein are illustrative in all respects, and are not restrictive. Indeed, the embodiments described above can be implemented in various forms. In addition, in the embodiments described above, omissions, replacements or changes may be made in various forms without departing from the appended claims and the spirit thereof.

In addition, in relation to the embodiments described above, the following supplements are further disclosed. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

### Supplementary Note 1

A plasma processing method, comprising:
a1) coating surfaces of a component in a chamber with a conductive film by turning a first gas and a second gas into plasma in the chamber;
a2) introducing a substrate into the chamber; and
a3) processing the substrate by turning a third gas into plasma in the chamber in a state where the surface of the component in the chamber is coated with the conductive film,
the first gas containing at least one of carbon, silicon and germanium, and
the second gas containing at least one of boron, nitrogen, phosphorus and arsenic.

### Supplementary Note 2

The plasma processing method according to Supplementary Note 1, wherein
in the a1), the surface of the component in the chamber is coated with the conductive film by turning the first gas and the second gas into plasma in the chamber in a state where an inside of the chamber is supplied with both the first gas and the second gas.

### Supplementary Note 3

The plasma processing method according to Supplementary Note 1, wherein
in the a1), the surface of the component in the chamber is coated with the conductive film by turning the second gas into plasma after turning the first gas into plasma in the chamber.

### Supplementary Note 4

The plasma processing method according to any one of Supplementary Notes 1 to 3, wherein the first gas contains at least one of hydrocarbon gas, hydrofluorocarbon gas, fluorocarbon gas and carbon tetrachloride gas.

### Supplementary Note 5

The plasma processing method according to any one of Supplementary Notes 1 to 3, wherein the first gas contains at least one of aminosilane gas, monosilane gas, disilane gas, dichlorosilane gas, silicon tetrachloride gas and silicon tetrafluoride gas.

### Supplementary Note 6

The plasma processing method according to any one of Supplementary Notes 1 to 3, wherein the first gas contains at least one of monogermane gas and germanium tetrachloride gas.

### Supplementary Note 7

The plasma processing method according to any one of Supplementary Notes 1 to 3, wherein the second gas contains at least one of boron trifluoride gas, boron trichloride gas, monoborane gas, diborane gas and boron tribromide gas.

### Supplementary Note 8

The plasma processing method according to any one of Supplementary Notes 1 to 3, wherein the second gas contains at least one of nitrogen gas, ammonia gas, nitrogen trifluoride gas, nitrogen trichloride gas, nitrogen monoxide gas, nitrous oxide gas, nitrogen dioxide gas and trimethylamine gas.

### Supplementary Note 9

The plasma processing method according to any one of Supplementary Notes 1 to 3, wherein the second gas contains at least one of phosphorus trifluoride gas, phosphorus trichloride gas, phosphine gas, phosphorus pentafluoride gas, phosphorus pentachloride gas, phosphorus tribromide gas and phosphoryl chloride gas.

### Supplementary Note 10

The plasma processing method according to any one of Supplementary Notes 1 to 3, wherein the second gas contains at least one of arsine gas, arsenic trifluoride gas, arsenic pentafluoride gas, arsenic trichloride gas and arsenic pentachloride gas.

### Supplementary Note 11

A plasma processing method, comprising:
b1) arranging a target containing a predetermined element in a chamber;
b2) coating surfaces of a component in the chamber with a conductive film by turning a rare gas and an additive gas into plasma to sputter the target in the chamber;
b3) introducing a substrate into the chamber; and
b4) processing the substrate by turning a processing gas into plasma in the chamber in a state where the surface of the component in the chamber are coated with the conductive film,
the element being at least one of carbon, silicon and germanium, and
the additive gas containing at least one of boron, nitrogen, phosphorus and arsenic.

### Supplementary Note 12

The plasma processing method according to Supplementary Note 11, wherein in b2), atoms contained in the target are driven out by ions contained in the plasma and the atoms are deposited as a protective film on the surfaces of the components in the chamber.

### Supplementary Note 13

The plasma processing method according to Supplementary Note 12, wherein in b2), the additive gas contains at least one of boron, nitrogen, phosphorus and arsenic.

### Supplementary Note 14

The plasma processing method according to Supplementary Note 13, further comprising, after b2) and before b3), taking out the target from inside the chamber.

### Supplementary Note 15

The plasma processing method according to Supplementary Note 14, further comprising, after taking out the target and before b3), supplying a reforming gas into the chamber and turning the reforming gas into plasma to reform the protective film into a conductive protective film.

### Supplementary Note 16

The plasma processing method according to Supplementary Note 15, wherein the reforming gas contains at least one of boron, nitrogen, phosphorus and arsenic.

### Supplementary Note 17

A plasma processing apparatus comprising:
a chamber having a gas supply port and a gas discharge port;
a substrate support that is provided in the chamber, and supports a substrate;
a plasma generator that produces plasma from a gas supplied into the chamber; and
controller circuitry, wherein
the controller circuitry is configured to execute:
a1) coating a surface of a component in the chamber with a conductive film with a first gas and a second gas turned into plasma in the chamber by controlling the plasma generator;
a2) placing the substrate introduced into the chamber on the substrate support; and
a3) processing the substrate with a third gas turned into plasma in the chamber in a state where the surface of the component in the chamber is coated with the conductive film, by controlling the plasma generator,
the first gas contains at least one of carbon, silicon, and germanium, and
the second gas contains at least one of boron, nitrogen, phosphorus, and arsenic.

### Supplementary Note 18

The plasma processing apparatus according to Supplementary Note 17, wherein
in the a1), the surface of the component in the chamber is coated with the conductive film by turning the first gas and the second gas into plasma in the chamber in a state where an inside of the chamber is supplied with both the first gas and the second gas.

### Supplementary Note 19

The plasma processing apparatus according to Supplementary Note 17, wherein
in the a1), the surface of the component in the chamber is coated with the conductive film by turning the second gas into plasma after turning the first gas into plasma in the chamber.

### Supplementary Note 20

The plasma processing apparatus according to Supplementary Note 17, wherein the first gas contains at least one of hydrocarbon gas, hydrofluorocarbon gas, fluorocarbon gas and carbon tetrachloride gas.

What is claimed is

1. A plasma processing method, comprising:
a1) coating surfaces of a component in a chamber with a conductive film by turning a first gas and a second gas into plasma in the chamber;
a2) introducing a substrate into the chamber; and
a3) processing the substrate by turning a third gas into plasma in the chamber in a state where the surface of the component in the chamber is coated with the conductive film,
the first gas containing at least one of carbon, silicon and germanium, and
the second gas containing at least one of boron, nitrogen, phosphorus and arsenic.

2. The plasma processing method according to claim 1, wherein
in the a1), the surface of the component in the chamber is coated with the conductive film by turning the first gas and the second gas into plasma in the chamber in a state where an inside of the chamber is supplied with both the first gas and the second gas.

3. The plasma processing method according to claim 1, wherein
in the a1), the surface of the component in the chamber is coated with the conductive film by turning the second gas into plasma after turning the first gas into plasma in the chamber.

4. The plasma processing method according to claim 1, wherein the first gas contains at least one of hydrocarbon gas, hydrofluorocarbon gas, fluorocarbon gas and carbon tetrachloride gas.

5. The plasma processing method according to claim 1, wherein the first gas contains at least one of aminosilane gas, monosilane gas, disilane gas, dichlorosilane gas, silicon tetrachloride gas and silicon tetrafluoride gas.

6. The plasma processing method according to claim 1, wherein the first gas contains at least one of monogermane gas and germanium tetrachloride gas.

7. The plasma processing method according to claim 1, wherein the second gas contains at least one of boron trifluoride gas, boron trichloride gas, monoborane gas, diborane gas and boron tribromide gas.

8. The plasma processing method according to claim 1, wherein the second gas contains at least one of nitrogen gas, ammonia gas, nitrogen trifluoride gas, nitrogen trichloride gas, nitrogen monoxide gas, nitrous oxide gas, nitrogen dioxide gas and trimethylamine gas.

9. The plasma processing method according to claim 1, wherein the second gas contains at least one of phosphorus trifluoride gas, phosphorus trichloride gas, phosphine gas, phosphorus pentafluoride gas, phosphorus pentachloride gas, phosphorus tribromide gas and phosphoryl chloride gas.

10. The plasma processing method according to claim 1, wherein the second gas contains at least one of arsine gas, arsenic trifluoride gas, arsenic pentafluoride gas, arsenic trichloride gas and arsenic pentachloride gas.

11. A plasma processing method, comprising:
b1) arranging a target containing a predetermined element in a chamber;
b2) coating surfaces of components in the chamber with a conductive film by turning a rare gas and an additive gas into plasma to sputter the target in the chamber;
b3) introducing a substrate into the chamber; and
b4) processing the substrate by turning a processing gas into plasma in the chamber in a state where the surface of the component in the chamber are coated with the conductive film,
the element being at least one of carbon, silicon and germanium, and
the additive gas containing at least one of boron, nitrogen, phosphorus and arsenic.

12. The plasma processing method according to claim 11, wherein in b2), atoms contained in the target are driven out by ions contained in the plasma and the atoms are deposited as a protective film on the surfaces of the components in the chamber.

13. The plasma processing method according to claim 12, wherein in b2), the additive gas contains at least one of boron, nitrogen, phosphorus and arsenic.

14. The plasma processing method according to claim 13, further comprising, after b2) and before b3), taking out the target from inside the chamber.

15. The plasma processing method according to claim 14, further comprising, after taking out the target and before b3), supplying a reforming gas into the chamber and turning the reforming gas into plasma to reform the protective film into a conductive protective film.

16. The plasma processing method according to claim 15, wherein the reforming gas contains at least one of boron, nitrogen, phosphorus and arsenic.

17. A plasma processing apparatus comprising:
a chamber having a gas supply port and a gas discharge port;
a substrate support that is provided in the chamber, and supports a substrate;
a plasma generator that produces plasma from a gas supplied into the chamber; and
controller circuitry, wherein
the controller circuitry is configured to execute:
a1) coating a surface of a component in the chamber with a conductive film with a first gas and a second gas turned into plasma in the chamber by controlling the plasma generator;
a2) placing the substrate introduced into the chamber on the substrate support; and
a3) processing the substrate with a third gas turned into plasma in the chamber in a state where the surface of the component in the chamber is coated with the conductive film, by controlling the plasma generator,
the first gas contains at least one of carbon, silicon, and germanium, and
the second gas contains at least one of boron, nitrogen, phosphorus, and arsenic.

18. The plasma processing apparatus according to claim 17, wherein in the a1), the surface of the component in the chamber is coated with the conductive film by turning the first gas and the second gas into plasma in the chamber in a state where an inside of the chamber is supplied with both the first gas and the second gas.

19. The plasma processing apparatus according to claim 17, wherein in the a1), the surface of the component in the chamber is coated with the conductive film by turning the second gas into plasma after turning the first gas into plasma in the chamber.

20. The plasma processing apparatus according to claim 17, wherein the first gas contains at least one of hydrocarbon gas, hydrofluorocarbon gas, fluorocarbon gas and carbon tetrachloride gas.
